(19) United States
(12) Patent Application Publication
(10) Pub. No.: US 2026/0190911 A1
(43) Pub. Date: Jul. 2, 2026

(54) MICROWAVE ANNEALING APPARATUS AND METHOD

(71) Applicants: MEI LIN Holdings Ltd., Kaohsiung City (TW); MEI LIN ENERGY TECHNOLOGY CO., Ltd., Kaohsiung City (TW)

(72) Inventors: Min-Hang Weng, Kaohsiung City (TW); Ru-Yuan Yang, Kaohsiung City (TW); Wu-Yeh Lee, Kaohsiung City (TW); Pai-Yi Hsueh, Kaohsiung City (TW)

(73) Assignees: MEI LIN Holdings Ltd., Kaohsiung City (TW); MEI LIN ENERGY TECHNOLOGY CO., Ltd., Kaohsiung City (TW)

(21) Appl. No.: 19/177,498

(22) Filed: Apr. 11, 2025

(30) Foreign Application Priority Data
Dec. 30, 2024 (TW) 113151831

(51) Int. Cl. H01L 21/67; F27B 17/00; F27D 5/00; F27D 7/02; F27D 11/12; H05B 6/64; H05B 6/74; H05B 6/80

(52) U.S. Cl. CPC H10P 72/0436; F27B 17/0025; F27D 5/0037; F27D 7/02; F27D 11/12; H05B 6/6408; H05B 6/74; H05B 6/80; H05B 2206/044

(57) ABSTRACT

The present disclosure provides a microwave annealing apparatus including: a heating chamber defined by a housing provided with multiple microwave power sources electrically connected to microwave power supplies and configured to provide a microwave heating state for an integrated electronic component to be heated; a cooling temperature control module configured to provide a temperature state for the integrated electronic component to be cooled; a gas pipeline module configured to provide a gas state for the integrated electronic component to be treated; an operation interface module configured to set a plurality of process parameters for the microwave annealing apparatus; and a control module configured to control activation and deactivation of the microwave power supplies, the cooling temperature control module, and the gas pipeline module. The microwave annealing apparatus can provide rapid, stable, and uniform heating for multiple integrated electronic components.

### CROSS-REFERENCE TO RELATED APPLICATION

This application claims priority to and the benefit of Taiwan Patent Application Ser. No. 113151831, filed on Dec. 30, 2024, the entirety of which is incorporated by reference herein.

### FIELD

The present disclosure relates to an annealing apparatus and method, particularly to a microwave annealing apparatus and method.

### BACKGROUND

With the rapid expansion of emerging technologies such as 5G, the Internet of Things, and high-performance computing, the semiconductor market continues to thrive. To meet this wave of demand, the silicon nano-semiconductor component industry, the third-generation optoelectronic semiconductor (e.g., SiC or GaN) industry, and the advanced thin-film interface synthesis industry are continuously expanding.

In the front-end, back-end, or packaging manufacturing processes of semiconductors, heating annealing modification is required for dopant activation, defect repair, or polymer curing. Annealing techniques include tube furnace processing, rapid thermal processing (RTP), and rapid thermal annealing (RTA) including flash annealing and various types of laser annealing. The annealing process is generally carried out in a tube furnace, and wafers are placed in a high-temperature tube furnace to activate or repair semiconductor materials. However, the traditional tube furnace heating annealing, even with the rapid thermal processing (RTP) method, has reached its limits for precision semiconductor wafer fabrication.

A heating apparatus is used for heating objects and thus can be used for evaporation, sterilization, baking, etc. Microwaves are electromagnetic waves with frequencies ranging from 300 MHz to 300 GHz and commonly used for information transmission in radar and communication technologies. In recent years, microwaves have also been applied in various industrial and agricultural fields for heating, drying, or pyrolyzing materials. The power frequencies of the commonly used microwaves are 915 MHz and 2450 MHz, which can cause molecules of polar material to rub against each other to generate heat. The power frequency of the microwave can be selected according to the shape, size and moisture content of the heated material. Microwave heating makes the heated object itself become the heat source without the need for heat conduction, and the heating occurs simultaneously inside and outside, thus achieving the heating effect in a short time. Moreover, during microwave heating, electromagnetic waves typically penetrate evenly throughout all parts of the object to generate heat, thus significantly improving uniformity. In microwave heating, microwave energy is only absorbed by the heated object to generate heat while the air in the heating chamber and the corresponding container do not heat up, thus resulting in extremely high thermal efficiency and significantly improving production environments.

Therefore, for the next generation of high-precision silicon nano-semiconductor components, third-generation optoelectronic semiconductor (e.g., SiC or GaN) components, and advanced thin-film interface synthesis processes, the use of microwave heating is a forward-looking process that has the potential to replace the traditional heating. However, the current researches on microwave annealing for related semiconductor materials are still mostly at the laboratory level. In actual mass production, the apparatus and methods need to provide rapid, stable, and uniform heating for multiple semiconductor wafers. U.S. Pat. No. 7,928,021, titled: SYSTEM FOR AND METHOD OF MICROWAVE ANNEALING SEMICONDUCTOR MATERIAL, is the earliest patent application filed in 2007 that proposed a microwave annealing apparatus and method for semiconductor material. However, at that time, the wafer size was about 8 inches. The system disclosed in the patent application is a conceptual illustration and does not include the actual component setup architecture. Moreover, as of today, wafer sizes have reached 12 inches, which is about 30 centimeters in diameter. Achieving uniform and lower-temperature heating on current 12-inch wafers is a significant challenge.

In view of the above problems, it is necessary to provide a mass-production architecture for a microwave annealing apparatus and method to solve the aforementioned problems.

### SUMMARY

The primary objective of the present disclosure is to provide a microwave annealing apparatus that can achieve low-temperature, uniform microwave heating in a mass-production architecture for more integrated electronic components.

Another objective of the present disclosure is to provide a microwave annealing method that can provide more varied and uniform microwave power distribution to achieve rapid, stable, and uniform heating in a mass-production architecture.

In order to achieve the primary objective of the present disclosure, the present disclosure provides a microwave annealing apparatus including a heating chamber, a cooling temperature control module, a gas pipeline module, an operation interface module, and a control module.

According to one aspect of the present disclosure, the heating chamber is defined by a housing and provided with at least one carrier inside the housing to hold at least one integrated electronic component and a plurality of microwave power sources disposed on the housing. The plurality of microwave power sources are electrically and respectively connected to corresponding microwave power supplies and directed toward the heating chamber to provide a microwave heating state for the at least one integrated electronic component to be heated. The cooling temperature control module is disposed below the housing and configured to provide a temperature state to cool the at least one integrated electronic component on the at least one carrier. The gas pipeline module is disposed below the heating chamber and configured to introduce a gas through multiple air inlet holes in the housing of the heating chamber to provide a gas state. The operation interface module is configured to set a plurality of process parameters for the microwave annealing apparatus. The control module is electrically connected to the operation interface module, the microwave power supplies, the cooling temperature control module, and the gas pipeline module and configured to control, after the operation interface module sets the plurality of process parameters, activation and deactivation of the microwave power supplies, the cooling temperature control module, and the gas pipeline module to provide the microwave heating state, the temperature state, and the gas state.

According to one aspect of the present disclosure, the plurality of process parameters include at least one microwave heating parameter associated with the microwave heating state, at least one temperature parameter associated with the temperature state, and at least one gas parameter associated with the gas state. The at least one microwave heating parameter includes at least one of an activation and deactivation status of the microwave power sources, a microwave heating power, a microwave heating energy, a microwave power density, a microwave energy density, and a microwave electric field strength. The at least one temperature parameter includes at least one of a heating rate, a maintenance temperature, and a maintenance time for a constant temperature. The at least one gas parameter includes at least one of a gas type, a gas flow rate, and an oxygen concentration.

According to one aspect of the present disclosure, the microwave power sources are magnetrons with a power range from 800 W to 1500 W, disposed on multiple sides of the housing, and a microwave frequency of the microwave power sources is selected from 915 MHz, 2450 MHz, and 5800 MHz.

According to one aspect of the present disclosure, a distance between the microwave power sources disposed on the housing is between one-third microwave wavelengths and three microwave wavelengths to achieve a control condition for phase adjustment of the microwave frequency.

According to one aspect of the present disclosure, the heating chamber is further provided with a lifter inside, electrically connected to the control module inside, and configured to raise or lower the at least one carrier to reach the microwave heating state.

According to one aspect of the present disclosure, the control module is further configured to control the deactivation or the adjustment of at least one of the microwave power sources to provide different microwave power distributions inside the heating chamber.

According to one aspect of the present disclosure, the operation interface module is able to be remotely controlled to set the plurality of process parameters. After the plurality of process parameters are set, the control module controls the activation and the deactivation of the microwave power supplies, the cooling temperature control module, and the gas pipeline module.

In order to achieve another objective of the present disclosure, the present disclosure provides a microwave annealing method including the following steps:
Step 1: Load at least one integrated electronic component on at least one carrier disposed inside a heating chamber of a microwave annealing apparatus.
Step 2: Set a plurality of process parameters for the microwave annealing apparatus, wherein the plurality of process parameters include at least one microwave heating parameter, at least one temperature parameter, and at least one gas parameter.
Step 3: Use a control module to control the activation and the deactivation of a plurality of microwave power sources, a cooling temperature control module, and a gas pipeline module to provide a microwave heating state, a temperature state, and a gas state required by the at least one integrated electronic component.

According to one aspect of the present disclosure, the plurality of process parameters include at least one microwave heating parameter associated with the microwave heating state, at least one temperature parameter associated with the temperature state, and at least one gas parameter associated with the gas state. The at least one microwave heating parameter includes at least one of an activation and deactivation status of the microwave power sources, a microwave heating power, a microwave heating energy, a microwave power density, a microwave energy density, and a microwave electric field strength. The at least one temperature parameter includes at least one of a heating rate, a maintenance temperature, and a maintenance time for a constant temperature. The at least one gas parameter includes at least one of a gas type, a gas flow rate, and an oxygen concentration.

According to one aspect of the present disclosure, the control module is further configured to control the deactivation or the adjustment of at least one of the microwave power sources to provide different microwave power distributions inside the heating chamber.

According to one aspect of the present disclosure, a distance between the microwave power sources is between one-third microwave wavelengths and three microwave wavelengths.

According to one aspect of the present disclosure, every two adjacent microwave power sources of the microwave power sources are arranged in a vertically staggered manner, and a distance between the microwave power sources is between one-third microwave wavelengths and three microwave wavelengths.

With the technical features of the microwave annealing apparatus and method of the present disclosure, the outer surface of the housing of the heating chamber is provided with the plurality of microwave power sources. After the plurality of process parameters for the microwave annealing apparatus are set, the control module controls the activation and the deactivation of the microwave power supplies, the cooling temperature control module, and the gas pipeline module to provide the microwave heating state, the temperature state, and the gas state. Therefore, for semiconductor materials with different material characteristics, the microwave annealing apparatus and method of the present disclosure can provide fast, stable, and uniform heating required for a mass production architecture.

### BRIEF DESCRIPTION OF THE DRAWINGS

In order to make the above and other objectives, features, and advantages of the present disclosure more clearly understood, several preferred embodiments are listed and described below in detail with reference to the accompanying drawings.

FIG. 1 is a schematic diagram showing a microwave annealing apparatus according to an embodiment of the present disclosure.

FIG. 2 is a schematic diagram showing the arrangement of microwave power sources disposed on a housing defining a heating chamber according to an embodiment of the present disclosure.

FIG. 3 is a schematic diagram showing a microwave annealing method according to an embodiment of the present disclosure.

### DETAILED DESCRIPTION

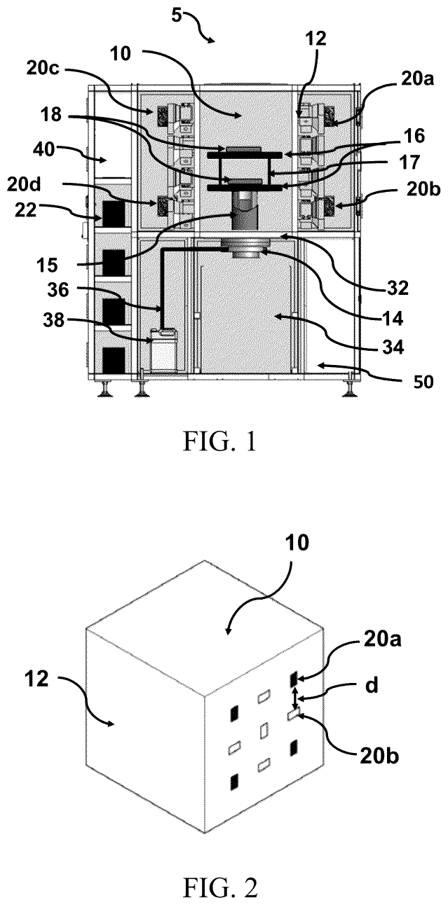

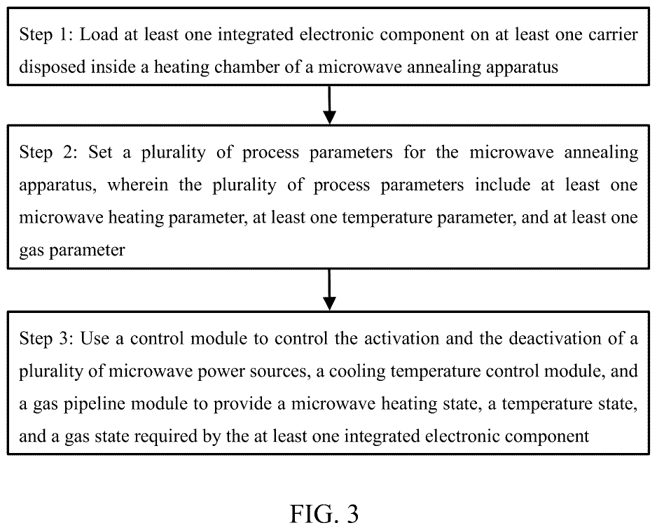

The embodiments of the present disclosure are described according to FIG. 1, FIG. 2, and FIG. 3. The descriptions are not intended to limit the embodiments of the present disclosure but are intended to describe exemplary embodiments. FIG. 1 is a schematic diagram showing a microwave annealing apparatus 5 according to an embodiment of the present disclosure. According to an embodiment of a mass production architecture of the present disclosure, the microwave annealing apparatus 5 includes a heating chamber 10 defined by a housing 12, a cooling temperature control module 14 disposed below the housing 12, a gas pipeline module 34 disposed below the heating chamber 10, an operation interface module 40, and a control module 50.

The housing 12 is provided with a plurality of microwave power sources 20a, 20b, 20c, 20d disposed thereon, and the heating chamber 10 is provided with at least one carrier 16 inside to carry at least one integrated electronic component 18. The microwave power sources 20a, 20b, 20c, 20d are electrically and respectively connected to corresponding microwave power supplies 22 and directed toward the heating chamber 10 to provide a microwave heating state for the integrated electronic components 18 to be heated inside the heating chamber 10. The microwave heating state is associated with at least one microwave heating parameter including at least one of an activation and deactivation status of the microwave power sources 20a, 20b, 20c, 20d, a microwave heating power, a microwave heating energy, a microwave power density, a microwave energy density, and a microwave electric field strength. The microwave heating energy is the microwave heating power multiplied by an operating time of the microwave power source, the microwave power density is defined as the microwave heating power per square centimeter, and the microwave energy density is defined as the microwave heating energy per square centimeter. The material of the housing 12 can be magnetic metal, magnetic ceramic, non-magnetic metal or non-magnetic ceramic. The thickness of the housing defining the heating chamber 10 is between 0.1 mm and 20 mm. The integrated electronic components 18 are multiple 12-inch wafers, which have high-precision silicon nano-semiconductor components, third-generation optoelectronic semiconductor (e.g., SiC or GaN) components, and/or advanced thin-film materials.

FIG. 2 is a schematic diagram showing the arrangement of microwave power sources disposed on a housing defining a heating chamber according to an embodiment of the present disclosure. It should be noted that in FIG. 1, the microwave power sources 20a, 20b, 20c, 20d are only for illustration only, not limited to four, and may be more or fewer. The microwave power sources 20a, 20b, 20c, 20d are disposed on multiple sides of the housing 12 defining the heating chamber 10. Preferably, the housing 12 defining a square chamber has six sides including top, bottom, left, right, front, and back slides. In particular, the microwave power sources 20a, 20b, 20c, 20d are disposed on two symmetrical sides of the housing 12 defining the heating chamber 10. For example, the heating chamber 10 has a chamber door (not shown) located at the front side of the housing 12, and the microwave power sources 20a, 20b, 20c, 20d are disposed on the left and right symmetrical sides of the chamber door of the heating chamber 10. In the present embodiment, the housing 12 defining the heating chamber 10 has two sides provided with the microwave power sources 20a, 20b, 20c, 20d, and each of these two sides is provided with four microwave power sources 20a, 20b, 20c, 20d arranged in four corners of a virtual square. In another embodiment, the microwave power sources 20a, 20b, 20c, 20d can also be disposed on one side or more than two sides of the housing 12, and the distribution position, quantity, and shape thereof are not limited thereto. The length, width, and height of the heating chamber 10 are all greater than 15 centimeters, and preferably, the length, width, and height of the heating chamber 10 are all between 50 centimeters and 150 centimeters to accommodate multiple 12-inch wafers.

The microwave power sources 20a, 20b, 20c, 20d are magnetrons with a power range from 800 W to 1500 W, and a microwave frequency of the microwave power sources 20a, 20b, 20c, 20d is selected from 915 MHz, 2450 MHz, and 5800 MHz. Therefore, the microwave power sources 20a, 20b, 20c, 20d can excite multiple modes inside the heating chamber 10. By adjusting the distance (d) between the microwave power sources 20a, 20b, 20c, 20d on the housing 12, a control condition for phase adjustment of the microwave frequency can be achieved. In one embodiment, the distance (d) between the microwave power sources 20a, 20b, 20c, 20d is between one-third microwave wavelengths and three microwave wavelengths to achieve a control condition for phase adjustment of the microwave frequency. For example, if the microwave frequency of the microwave power sources 20a, 20b, 20c, 20d is 2450 MHz, then one microwave wavelength is 12.5 cm, and the distance (d) between the microwave power sources 20a, 20b, 20c, 20d is between 4.15 cm and 37.5 cm. To further achieve microwave uniformity, every two adjacent microwave power sources of the microwave power sources 20a, 20b, 20c, 20d are arranged in a vertically staggered manner. In FIG. 2, for example, the microwave power source 20a and the microwave power source 20b are arranged in a vertically staggered manner, which allows the electromagnetic waves output by the adjacent microwave power sources to generate more fusion modes to reduce high points and low points of standing waves. In one embodiment, every two adjacent microwave power sources of the microwave power sources 20a, 20b, 20c, 20d are arranged in a vertically staggered manner, and a distance (d) between the microwave power sources is between one-third microwave wavelengths and three microwave wavelengths.

The heating chamber is further provided with a lifter 15 inside. The lifter 15 is electrically connected to the control module 50 and configured to raise or lower the at least one carrier 16 to a desired height. In FIG. 1, the at least one carrier 16 includes two carriers, and a support frame 17 are supported between the two carriers. However, the at least one carrier 16 is not limited to two. Preferably, the number of the at least one carrier 16 is between one and twenty. Moreover, the carrier 16 is preferably circular, and the diameter of the carrier 16 is between 30 cm and 40 cm.

The cooling temperature control module 14 is disposed below the housing 10 and configured to provide a temperature state to cool the integrated electronic components 18 on the at least one carrier 16. The temperature state is associated with at least one temperature parameter including at least one of a heating rate, a maintenance temperature, and a maintenance time for a constant temperature. The at least one carrier 16 is provided with at least one thermocouple temperature sensing component (not shown) electrically connected to the cooling temperature control module 14 to sense a temperature of the integrated electronic components 18 on the at least one carrier 16.

The gas pipeline module 34 is disposed below the heating chamber 10 and configured to introduce a gas through multiple air inlet holes 32 of the housing 10 to provide a gas state. The gas state is associated with at least on gas parameter including at least one of a gas type, a gas flow rate, and an oxygen concentration. Preferably, the gas type includes argon, nitrogen, hydrogen, and/or oxygen.

The operation interface module 40 is configured to set a plurality of process parameters for the microwave annealing apparatus 5, and the plurality of process parameters include the at least one microwave heating parameter, the at least one temperature parameter, and the at least one gas parameter. The at least one microwave heating parameter includes at least one of an activation and deactivation status of the microwave power sources 20a, 20b, 20c, 20d, a microwave heating power, a microwave heating energy, a microwave power density, a microwave energy density, and a microwave electric field strength. The at least one temperature parameter includes at least one of a heating rate, a maintenance temperature, and a maintenance time for a constant temperature. The at least one gas parameter includes at least one of a gas type, a gas flow rate, and an oxygen concentration. It should be noted that in order to meet the heating requirements for different materials, the above process parameters need to be adjusted, but not every parameter needs to be used, and the parameter to be used should be selected according to the status of the material.

The operation interface module 40 is able to be remotely controlled to set the plurality of process parameters. After the plurality of process parameters are set, the control module 50 controls the activation and the deactivation of the microwave power supplies 22, the cooling temperature control module 14, and the gas pipeline module 34.

The control module 50 is electrically connected to the operation interface module 40, the microwave power supplies 22, the cooling temperature control module 14, and the gas pipeline module 34 and configured to control, after the operation interface module 40 sets the plurality of process parameters, activation and deactivation of the microwave power supplies 22, the cooling temperature control module 14, and the gas pipeline module 34 to provide the microwave heating state, the temperature state, and the gas state.

The plurality of process parameters include at least one microwave heating parameter associated with the microwave heating state, at least one temperature parameter associated with the temperature state, and at least one gas parameter associated with the gas state. The at least one microwave heating parameter includes at least one of an activation and deactivation status of the microwave power sources, a microwave heating power, a microwave heating energy, a microwave power density, a microwave energy density, and a microwave electric field strength, the at least one temperature parameter includes at least one of a heating rate, a maintenance temperature, and a maintenance time for a constant temperature, and the at least one gas parameter includes at least one of a gas type, a gas flow rate, and an oxygen concentration.

The microwave annealing apparatus 5 further includes a vacuum module 38 electrically connected to the control module 50 and configured to extract, via a vacuum pumping pipeline 36, a gas from the heating chamber 10 to achieve a high vacuum state from a low vacuum state.

FIG. 3 is a schematic diagram showing a microwave annealing method according to an embodiment of the present disclosure. The present disclosure provides a microwave annealing method including the following steps:
Step 1: Load at least one integrated electronic component on at least one carrier disposed inside a heating chamber of a microwave annealing apparatus.
Step 2: Set a plurality of process parameters for the microwave annealing apparatus, wherein the plurality of process parameters include at least one microwave heating parameter, at least one temperature parameter, and at least one gas parameter.
Step 3: Use a control module to control the activation and the deactivation of a plurality of microwave power sources, a cooling temperature control module, and a gas pipeline module to provide a microwave heating state, a temperature state, and a gas state required by the at least one integrated electronic component.

The plurality of process parameters include at least one microwave heating parameter associated with the microwave heating state, at least one temperature parameter associated with the temperature state, and at least one gas parameter associated with the gas state. The at least one microwave heating parameter includes at least one of an activation and deactivation status of the microwave power sources 20a, 20b, 20c, 20d, a microwave heating power, a microwave heating energy, a microwave power density, a microwave energy density, and a microwave electric field strength, the at least one temperature parameter includes at least one of a heating rate, a maintenance temperature, and a maintenance time for a constant temperature, and the at least one gas parameter includes at least one of a gas type, a gas flow rate, and an oxygen concentration.

The control module is further configured to control the deactivation or the adjustment of at least one of the microwave power sources to provide different microwave power distributions inside the heating chamber.

The distance between the microwave power sources 20a, 20b, 20c, 20d is between one-third microwave wavelengths and three microwave wavelengths. Preferably, every two adjacent microwave power sources of the microwave power sources 20a, 20b, 20c, 20d are arranged in a vertically staggered manner, and a distance between the microwave power sources is within a range between one-third microwave wavelengths and three microwave wavelengths.

With the technical features of the microwave annealing apparatus of the present disclosure, the control module controls the activation and the deactivation of the microwave power supplies, the cooling temperature control module, and the gas pipeline module to provide the microwave heating state, the temperature state, and the gas state. Therefore, for semiconductor materials with different material characteristics, the microwave annealing apparatus of the present disclosure can provide fast, stable, and uniform heating.

The above descriptions are only illustrative for the preferred embodiments of the present disclosure. Those with ordinary knowledge in the art can make other modifications based on the appended claims and the above descriptions, but these modifications should still fall within the scope of the claimed invention.

What is claimed is:

1. A microwave annealing apparatus, comprising:
a heating chamber defined by a housing and provided with at least one carrier inside the housing to hold at least one integrated electronic component and a plurality of microwave power sources disposed on the housing, wherein the plurality of microwave power sources are electrically and respectively connected to corresponding microwave power supplies and directed toward the heating chamber to provide a microwave heating state for the at least one integrated electronic component to be heated;
a cooling temperature control module disposed below the housing and configured to provide a temperature state to cool the at least one integrated electronic component on the at least one carrier;
a gas pipeline module disposed below the heating chamber and configured to introduce a gas through a plurality of air inlet holes in the housing of the heating chamber to provide a gas state;
an operation interface module configured to set a plurality of process parameters for the microwave annealing apparatus; and
a control module electrically connected to the operation interface module, the microwave power supplies, the cooling temperature control module, and the gas pipeline module and configured to control, after the operation interface module sets the plurality of process parameters, activation and deactivation of the microwave power supplies, the cooling temperature control module, and the gas pipeline module to provide the microwave heating state, the temperature state, and the gas state, wherein:
the plurality of process parameters include at least one microwave heating parameter associated with the microwave heating state, at least one temperature parameter associated with the temperature state, and at least one gas parameter associated with the gas state;
the at least one microwave heating parameter includes at least one of an activation and deactivation status of the microwave power sources, a microwave heating power, a microwave heating energy, a microwave power density, a microwave energy density, and a microwave electric field strength;
the at least one temperature parameter includes at least one of a heating rate, a maintenance temperature, and a maintenance time for a constant temperature; and
the at least one gas parameter includes at least one of a gas type, a gas flow rate, and an oxygen concentration.

2. The microwave annealing apparatus of claim 1, wherein the microwave power sources are magnetrons with a power range from 800 W to 1500 W, disposed on a plurality of sides of the housing, and a microwave frequency of the microwave power sources is selected from 915 MHz, 2450 MHz, and 5800 MHz.

3. The microwave annealing apparatus of claim 1, wherein a distance between the microwave power sources disposed on the housing is between one-third microwave wavelengths and three microwave wavelengths to achieve a control condition for phase adjustment of the microwave frequency.

4. The microwave annealing apparatus of claim 1, wherein the heating chamber is further provided with a lifter inside, electrically connected to the control module inside, and configured to raise or lower the at least one carrier to reach the microwave heating state.

5. The microwave annealing apparatus of claim 1, wherein the control module is further configured to control the deactivation or adjustment of at least one of the microwave power sources to provide different microwave power distributions inside the heating chamber.

6. The microwave annealing apparatus of claim 1, wherein the operation interface module is able to be remotely controlled to set the plurality of process parameters; and after the plurality of process parameters are set, the control module controls the activation and the deactivation of the microwave power supplies, the cooling temperature control module, and the gas pipeline module.

7. A microwave annealing method, comprising:
loading at least one integrated electronic component on at least one carrier disposed inside a heating chamber of a microwave annealing apparatus;
setting a plurality of process parameters for the microwave annealing apparatus, wherein the plurality of process parameters include at least one microwave heating parameter, at least one temperature parameter, and at least one gas parameter; and
using a control module to control activation and deactivation of a plurality of microwave power sources, a cooling temperature control module, and a gas pipeline module to provide a microwave heating state, a temperature state, and a gas state required by the at least one integrated electronic component, wherein:
the plurality of process parameters include at least one microwave heating parameter associated with the microwave heating state, at least one temperature parameter associated with the temperature state, and at least one gas parameter associated with the gas state;
the at least one microwave heating parameter includes at least one of an activation and deactivation status of the microwave power sources, a microwave heating power, a microwave heating energy, a microwave power density, a microwave energy density, and a microwave electric field strength;
the at least one temperature parameter includes at least one of a heating rate, a maintenance temperature, and a maintenance time for a constant temperature; and
the at least one gas parameter includes at least one of a gas type, a gas flow rate, and an oxygen concentration.

8. The microwave annealing method of claim 7, wherein the control module is further configured to control the deactivation or adjustment of at least one of the microwave power sources to provide different microwave power distributions inside the heating chamber.

9. The microwave annealing method of claim 7, wherein a distance between the microwave power sources is between one-third microwave wavelengths and three microwave wavelengths.

10. The microwave annealing method of claim 7, wherein every two adjacent microwave power sources of the microwave power sources are arranged in a vertically staggered manner, and a distance between the microwave power sources is between one-third microwave wavelengths and three microwave wavelengths.
